(19) United States
(12) Patent Application Publication
(10) Pub. No.: US 2025/0151204 A1
(43) Pub. Date: May 8, 2025

(54) POLYMER-CONDUCTOR MATRIX ELECTRICAL INTERCONNECT

(71) Applicant: Worcester Polytechnic Institute, Worcester, MA (US)

(72) Inventors: Pratap Rao, Northborough, MA (US); Ritwik Pandey, Worcester, MA (US); Ceren Yilmaz Akkaya, Worcester, MA (US); Markus P. Nemitz, Southborough, MA (US); Cem Aygul, Worcester, MA (US)

(21) Appl. No.: 18/936,456

(22) Filed: Nov. 4, 2024

Related U.S. Application Data
(60) Provisional application No. 63/596,135, filed on Nov. 3, 2023.

(51) Int. Cl. H05K 3/10; H05K 3/04; H05K 3/06

(52) U.S. Cl. CPC H05K 3/107; H05K 3/04; H05K 3/06

(57) ABSTRACT

A surface treatment of a printed trace improves electrical conductivity at a contact area defining an insertion or engagement of a circuit element. Mechanical and chemical treatment at a contact area of an extruded trace generated from 3-dimensional (3D) printing techniques mitigates resistance of the surface. A conductive trace may be extruded from a conductive filament material including conductive granules, flakes or powder. A solvent or etchant applied to the extruded surface at the contact point removes, dissolves or otherwise abrades the contact area. A mechanical drilling or incision may also be applied. Dissolution of the non-conductive material exposes the conductive material for improved contact with a conductive epoxy or paste applied to the contact area for receiving a conductive terminal (pin or pad) from a circuit element.

### RELATED APPLICATIONS

This patent application claims the benefit under 35 U.S.C. § 119(e) of U.S. Provisional Patent App. No. 63/596,135, filed Nov. 3, 2023, entitled “ALKALI MICROWAVE EXTRACTION,” incorporated herein by reference in entirety.

### BACKGROUND

3 dimensional (3D) printing has gained popularity in recent years for physical renderings of objects by extrusion of a hot, molten polymer substance in carefully controlled droplets. More recently, addition of conductive materials into the polymer substance, generally soled as a spool of filament for a printer feed, allows printing of circuit traces due to the conductive properties afforded by the granular conductive materials. Conductive fused filaments are used to 3D-print circuits, including as part of 3D-printed structures consisting of both non-conductive and conductive parts. Electrical components such as packaged ICs and passives need to be attached to these 3D-printed circuits to create functional devices.

### SUMMARY

A surface treatment of a printed trace improves electrical conductivity at a contact area defining an insertion or engagement of a circuit element. Mechanical and chemical treatment at the contact area of an extruded trace generated from 3-dimensional (3D) printing techniques mitigates resistance of the surface. A conductive trace may be extruded from a conductive filament material including conductive granules, flakes or powder. A solvent or etchant applied to the extruded surface at the contact point removes, dissolves or otherwise abrades the contact area. A mechanical drilling or incision may also be applied. Dissolution of the non-conductive material exposes the conductive material for improved contact with a conductive epoxy or paste applied to the contact area for receiving a conductive terminal (pin or pad) from a circuit element.

Configurations herein are based, in part, on the observation that circuit traces printed by 3D printer extrusion offer advantages over conventional copper plate processing for forming electrical circuits on a surface. Granular conductive material embedded in a printing filament, typically a polymer, imparts conductivity to the printed traces. Unfortunately, conventional approaches to printed circuits and circuit boards suffer from the shortcoming that contact resistance at circuit element attachments impedes electrical performance at the contact area. Accordingly, configurations herein substantially overcome the shortcomings of printed, conductive traces by providing a chemical treatment at the contact area for removal or mitigation of the polymer filament material while leaving the conductive flakes or granules exposed for electrical communication with an attached circuit element.

In further detail, the disclosed method for forming a printed circuit includes extruding a surface from a liquid feedstock having conductive and nonconductive materials, and applying a solvent to a contact area of the extruded surface. A conductive material is deposited or extruded onto the contact area to form a trace, where the conductive material has a lower resistance than the liquid feedstock, and a conductive terminal of a circuit element is deposited into the conductive material.

### BRIEF DESCRIPTION OF THE DRAWINGS

The foregoing and other features will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles of the invention.

FIG. 1 is a context diagram of a conductive terminal or electrode attached according to configurations hereon; and

FIG. 2 is a schematic side view of a printed circuit using the approach of FIG. 1 for component (circuit element) attachment.

### DETAILED DESCRIPTION

Configurations herein decrease electrical contact resistance between a polymer-conductor matrix material conductive filament and a packaged electronic component, using mechanical material removal (drilling) and a solvent to dissolve, abrade or otherwise mitigate the polymer. Any suitable conductive filament may be employed, such as PLA (polylactic acid), ABS (Acrylonitrile Butadiene Styrene), engineering materials such as PA(Polyamide), TPU (thermoplastic polyurethane), PETG (polyethylene terephthalate glycol), PLA (polylactic acid), and ABS, engineering materials like PA, TPU (thermoplastic polyurethane), and PETG. Filaments are employed by FDM (Fused Deposition Modelling) 3D printing and FFF (Fused Filament Fabrication), which continue to emerge as promising additive manufacturing techniques.

The filament material is typically a thermoplastic polymer, which is generally an electrical insulator with high resistance. Embedded conductive particles provide a conductive path for formation as electrical traces. The solvent or etchant selectively dissolves or reacts with the nonconductive polymer component but does not react or dissolve the conductive material.

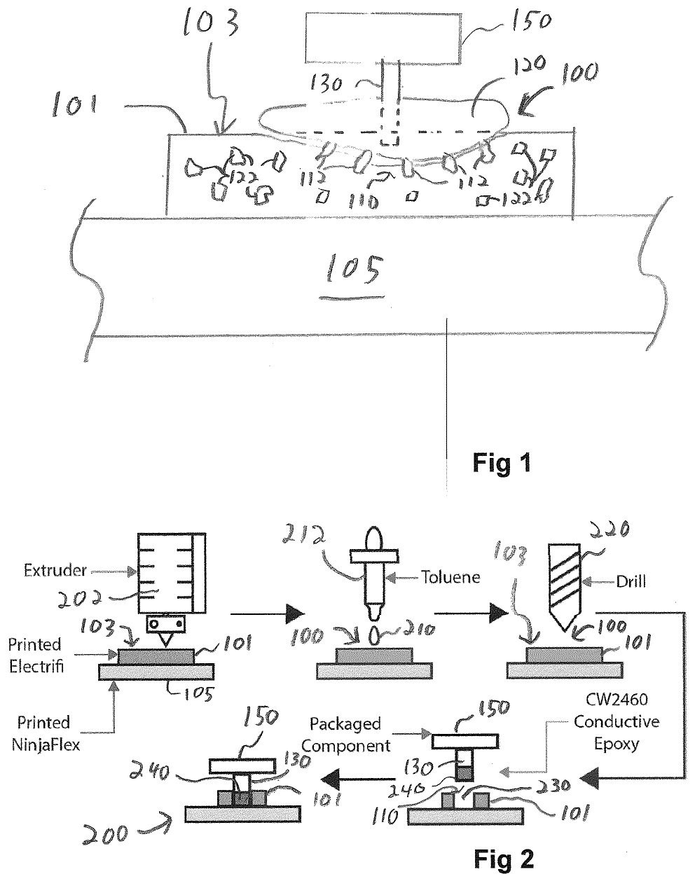

FIG. 1 is a context diagram of a conductive terminal or electrode attached according to configurations here. Fused deposition modeling (FDM) 3D printing, also known as fused filament fabrication (FFF), are labels for extruded polymers for 3D printing with the thermoplastics disclosed above. Conductive filaments embed conductive particles or flakes into the filament. Circuit fabrication involves printing of a modest thickness surface or trace along a substrate for defining conductive regions. Circuit elements or components attach to the circuit substrate with a conductive material such as a paste or epoxy, typically an uncured liquid with embedded silver or other conductive particles.

Merely dispensing the conductive paste onto the substrate results in substantial resistance between the printed trace and circuit element. This may be due to a surface property of the extruded, printed trace, a settling of conductive particles away from the surface, or a limited exposure of the conductive particles at the trace surface. Referring to FIG. 1, a side view of a contact area 100 on an extruded surface 103 of a printed trace 101 on a circuit board 105 or material is shown. The extruded surface 103 is from a feedstock of a conductive filament. A treated region 110 at the contact area 100 has exposed particles 112 resulting from abrading, dissolving, or etching by a solvent. Unexposed conductive particles 122 remain dispersed throughout the printed trace 101, and contribute to overall conductivity of the trace 101. The conductive material 120 applied at the contact 100 receives a conductive terminal 130 inserted into the conductive material 120, forming a conductive path from the circuit element 150 to the printed trace 101.

Mechanical treatment at the contact area 100, such as drilling, grinding or surface abrasion, may remove a small amount of material, resulting in the treated region 110 departing from flush with the printed trace 101, or material may or may not be removed by the solvent treatment. The conductive material 120 may extend above the extruded surface 101, and receives the conductive terminal 130 of a circuit element 150. Most circuit elements include a plurality of conductive terminals, taking the form of a row of pins or ordered array such as a square or triangular orientation. Therefore precise location of the treated region 110 and subsequent conductive material 120 deposition is significant.

FIG. 2 is a schematic side view of a printed circuit using the approach of FIG. 1 for component (circuit element) attachment. Fabrication commences with printing an FFF circuit structure with conductive portions defining traces, and designating the contact area within the conductive portions. FIG. 2 demonstrates that, following the print of copper-filled traces, toluene is used to remove the polymerizing agent to expose copper. Material is removed at the designated contact point by means of drilling. The packaged component is attached to the contact location using a conductive epoxy.

Referring to FIGS. 1 and 2, the disclosed approach for forming a printed circuit includes extruding the surface 103 as a trace 101 from a liquid feedstock 202 having conductive and nonconductive materials, such as a conductive filament as disclosed above. The liquid feedstock is a conductive printing material including a meltable polymer and an embedded granular conductive material 112, 122, heated to a flowable state for extrusion. The trace 101 may be printed on a suitable rigid circuit board 105 or similar surface, or may be a flexible or deformable material for applications such as soft robotics. A carefully metered drop 210 or quantity of a solvent, such as toluene, is applied to the contact area 100 of the extruded surface 103 from a spray or pump apparatus 212. The solvent exposes the conductive materials 112 on the extruded surface 103 from dissolution of the nonconductive material at the contact area 100, and reduces electrical resistance on the surface. If follows that the solvent should be selected based on a responsiveness of the non-conductive materials to the solvent and resistance of the conductive material to the solvent.

The contact area 100 is agitated with a mechanical abrasion such as a drill 220, in conjunction with applying the solvent. This may involve mechanically removing a portion of the extruded surface 103 from the contact area 100, causing the treated region 110 to erode in a concave or cylindrical manner. Less invasive abrasion may include sanding or roughing the surface. Applying a combination of chemical and mechanical abrasion to the extruded surface 103 exposes conductive materials on are near the surface for greater electrical conductivity/continuity with a subsequently applied conductive epoxy or similar conductive material. The mechanical treatment complements the solvent by reducing any surface resistance that tends to persist in the extruded surface 103.

The chemical treatment of the solvent 210, along with the mechanical treatment of drilling or abrasion, form a receptacle 230 from the cylindrical or concave formation at the treated region 110. Whether a receptacle 230 is formed or the treatment area 100 remains flush, a conductive material 240 is deposited onto the contact area, and is typically a conductive paste or epoxy. In general, the conductive material has a lower resistance than the liquid feedstock extruded to form the trace 101. The conductive material 240 will fill the receptacle 230 and/or accumulate in a convex deposit as in FIG. 1. The conductive material is in a liquid form upon deposition or extrusion. A conductive terminal 130 of a circuit element 150 is inserted into the conductive material 240, and upon hardening or curing, provides both electrical and mechanical properties to the attached circuit element 150. The extruder or print nozzle applies a pool or droplet of the conductive material to the contact area 100, and receives the conductive terminal into the liquid form of the conductive material, after which the conductive material solidifies to engage and attach the conductive terminal. Many circuit elements include a row of pins, each defining a conductive terminal 130, while discrete elements such as resistors, transistors, diodes, etc. typically have at least 2 or 3 conductive terminals 130. The overall result is superior mechanical and electrical engagement of the conductive terminal and corresponding circuit element.

In a particular use case, the disclosed approach may be invoked to integrate conductive materials into soft robots using multi-material fused deposition modeling, as one example. The approach deposits copper-filled conductive polymers and flexible thermoplastic polyurethane variations together in a singular print job to integrate electronics into soft robotic structures. The result is an attachment methodology that assures well-established electrical connections between the printed circuitry and the packaged components that are placed. The methodology does not only eliminate the cumbersome assembly steps for the integration of electronics into the robot body but also helps retain the compliant characteristics of soft robots. The use of a multi-material 3D printing of a soft car chassis allows embedding the circuitry during a single print job, demonstrating the integration of electronic components on the print bed; with minimal manual interventions to create an operational soft robot with integrated electronic circuitry.

Different methodologies exist to additively manufacture soft materials: Fused Deposition Modeling (FDM), Stereolithography (SLA), and Polyjet printing being the most commonly used ones. TPUs are commercially available as filament spools usable for FDM, featuring shore hardnesses as low as 60A (shore hardness designates the elasticity of a flexible filament). The softest materials are available for vat polymerization methods in resin form. These materials can be as soft as 35A, nearing the range of additive curing elastomers. However, due to the system architecture of SLA, only one resin can reside in the resin tank at a time; multi-material printing using PolyJet printing can achieve shore hardnesses as low as 00A, however, despite its promise, PolyJet printing generally remains prohibitively expensive. In an example configuration, thermoplastic polyurethane (TPU), which has a shore hardness of 85A and an extrusion temperature of 245° C., is employed for the conductive traces.

FDM printers can be modified for multi-material printing. Modifications include hot-end arrays, selector mechanisms, and splicers. Nonetheless, most of these methods are meant for multi-color printing of rigid materials such as PLA; they typically fail to print TPUs. Elastomeric filaments require constrained filament paths and distinct idler tensions, print temperatures, and cooling adjustments depending on their shore hardness. Therefore, configurations herein employ a tool-changer, a specialized 3D printer with multiple, independent tool heads. Different materials are assigned to different tool heads, and a selector mechanism picks up the corresponding tool according to the slicer output. This enables printing of different materials on every layer, and embedding of copper-filled conductive traces into soft TPUs.

Attachment of packaged components such as integrated circuits to a printed polymer-conductor matrix poses significant challenges primarily stemming from substantial contact resistances at interfaces. Available attachment methods to establish connections include the following:
Heat and Plunge: In this method, the polymer-conductor matrix (comprising a conductive Fused Deposition Modeling (FDM) printed trace) or the pads/legs of the electronic component are subjected to heating, followed by the insertion of the component;
Silver Paste/Conductive Epoxy: This approach involves the application of silver paste or conductive epoxy to the contact points, after which the electronic component is positioned. The epoxy is allowed to cure before using the circuit;
Hole Insertion: In this method, the legs of through-hole components are inserted into either pre-printed or drilled holes in the polymer-conductor matrix (conductive FDM printed trace); and
Melted Conductive Filament Interface: A small piece of conductive filament is melted and used as an intermediary between the electronic component and the polymer-conductor matrix (conductive FDM printed trace).

A particular use case investigated each of these attachment methods by printing 100 mm×2 mm×2 mm specimens and attaching breakaway headers at intervals of 30 mm. The resistance of the conductor-polymer matrix was quantifies using a 4-terminal probe (Hioki® RM3545), ˜0.83 Ω/cm with a 4 mm² cross-sectional area. This was employed to measure resistance per unit length to calculate the contact resistance, subtracting the resistance of the polymer-conductor matrix from the 2- terminal resistance measurement.

As shown in the result in Table I, notably high contact resistances are noted for the heat and plunge as well as melted filament attachment methods, rendering them unsuitable. In contrast, the use of conductive silver epoxy consistently yielded attachments with lower contact resistances. However, the contact resistances, ranging from 40Ω to 130Ω, still present a significant concern due to potential power waste. It demonstrates that the elevated contact resistances may be attributed to the polymer coating of the copper micro/nanoparticles within the printed polymer conductor matrix.

TABLE I
Attachment Methods

| | | Melted & | | | | | |
|---|---|---|---|---|---|---|---|
| Measure- | Heat & | Smashed | | | | | |
| ment | Plunge | Filament | Silver Epoxy | | Drilling | Toulene + Silver Epoxy | |
| No. | Inserted (Ω) | Surface (Ω) | Surface (Ω) | Drilled (Ω) | Inserted (Ω) | Surface (Ω) | Drilled (Ω) |
| 1 | 2259997.51 | 239999997.51 | 62.51 | 48.51 | 3397.51 | 11.03 | 10.26 |
| 2 | 2779997.51 | 153999997.51 | 84.51 | 131.51 | 2667.51 | 11.78 | 3.22 |
| 3 | 4749997.51 | 632.51 | 70.51 | 114.49 | 4557.51 | 10.08 | 3.82 |
| 4 | 3099992.53 | 409.53 | 40.53 | 117.53 | 33992.53 | 8.21 | 7.60 |

The disclosed approach therefore presents a circuit element attachment method, involving material removal through drilling and the use of a solvent to partially dissolve the polymer matrix and expose the copper infill. The polymer used may be a biodegradable polyester. In practice, printed specimens were subjected to various solvents, including acetone, 2-methoxyethanol, hexane, dimethylsulfoxide (DMSO), dimethylformamide (DMF), tetrahydrofuran (THF), and toluene, with the objective of assessing the meltability of the polyester. It was observed that both THF and toluene were successful in dissolving the polyester, however toluene is preferred as it is less hazardous.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method for forming a printed circuit, comprising:
extruding a surface from a liquid feedstock having conductive and nonconductive materials;
applying a solvent to a contact area of the extruded surface;
depositing a conductive material onto the contact area, the conductive material having a lower resistance than the liquid feedstock; and
inserting a conductive terminal of a circuit element into the conductive material.

2. The method of claim 1 further comprising exposing conductive materials on the extruded surface from dissolution of the nonconductive material at the contact area.

3. The method of claim 1 further comprising selecting the solvent based on a responsiveness of the non-conductive materials to the solvent and resistance of the conductive material to the solvent.

4. The method of claim 1 further comprising applying a combination of chemical and mechanical abrasion to the extruded surface for exposing conductive materials on the surface.

5. The method of claim 1 wherein the liquid feedstock is a conductive printing material including a meltable polymer and an embedded granular conductive material.

6. The method of claim 1 wherein extruding the surface further comprises:
printing an FFF circuit structure with conductive portions; and
designating the contact area within the conductive portions.

7. The method of claim 1 further comprising agitating the contact area with a mechanical abrasion before applying the solvent.

8. The method of claim 1 further comprising mechanically removing a portion of the extruded surface from the contact area.

9. The method of claim 1 further comprising forming the liquid feedstock from a filament of conductive print medium.

10. The method of claim 1 wherein the conductive material is in a liquid form upon deposition, further comprising:
receiving the conductive terminal into the liquid form of the conductive material; and
solidifying the conductive material to engage and attach the conductive terminal.

11. The method of claim 9 wherein the filament is a 3 dimensional print medium including at least one of PLA (polylactic acid), ABS (crylonitrile Butadiene Styrene), PA (Polyamide), TPU (thermoplastic polyurethane), and PETG (polyethylene terephthalate glycol).

12. The method of claim 1 wherein the solvent is selected form the group consisting of acetone, 2-methoxyethanol, hexane, dimethylsulfoxide (DMSO), dimethylformamide (DMF), tetrahydrofuran (THF) and toluene.

13. A method for forming a printed circuit, comprising:
forming a surface from a mixture of conductive and non-conductive materials;
applying a combination of chemical and mechanical abrasion to a conductive circuit surface for exposing conductive materials on the surface;
depositing a conductive material with adhesive and conductive properties onto the abraded area; and
inserting a conductive terminal of a circuit element into the conductive material.

14. The method of claim 13 wherein the conductive material has chemical ingredients for forming a rigid structure over time from reactions of the chemical ingredients.

15. The method of claim 13 wherein the conductive material is a molten form for solidifying from cooling over time.

16. The method of claim 13 wherein the conductive material is in a liquid form upon deposition, further comprising:
receiving the conductive terminal into the liquid form of the conductive material; and
solidifying the conductive material to engage and attach the conductive terminal.

17. An attached circuit element, comprising:
a solvent treated contact area on an extruded, conductive surface;
a conductive material applied onto the contact area, the conductive material having a lower resistance than the extruded conductive surface; and
a conductive terminal of a circuit element inserted into the conductive material for providing electrical continuity between the extruded conductive surface and the circuit element.
